(19) United States
(12) Patent Application Publication
(10) Pub. No.: US 2013/0229858 A1
(43) Pub. Date: Sep. 5, 2013

(54) Fault Tolerant Static Random-Access Memory

(71) Applicant: MAXWELL CONSULTING, Croton on Hudson, NY (US)

(72) Inventor: Joseph M. Pimbley, Croton on Hudson, NY (US)

(73) Assignee: MAXWELL CONSULTING, Croton on Hudson, NY (US)

(21) Appl. No.: 13/782,114

(22) Filed: Mar. 1, 2013

Related U.S. Application Data
(60) Provisional application No. 61/605,970, filed on Mar. 2, 2012.

(51) Int. Cl. G11C 11/41

(52) U.S. Cl. CPC G11C 11/41
USPC 365/154

(57) ABSTRACT

A memory apparatus comprising a pathway for conducting electrical energy; a plurality of even number of inverters, each inverter having an input and an output, the inverters being arranged along the pathway such that electrical energy from the output of an inverter is directed into the input of an adjacent inverter; a plurality of nodes coupling the inverters in series to form a closed loop to permit stable storage of a memory state by allowing the inverters to dissipate an amount of transient energy from a level that otherwise would result in a failure to below that level in order to maintain a stable memory state.

### CROSS-REFERENCE TO RELATED APPLICATIONS

This application claims priority to and benefit of Provisional Patent Application Ser. No. 61/605,970, filed on Mar. 2, 2012. Application 61/605,970 is incorporated herein by reference in its entirety.

### FIELD OF THE DISCLOSURE

The current disclosure relates to computer memory, and, more particularly, to fault tolerant static random-access memory (“SRAM”).

### BACKGROUND

Various types of random-access memory (“RAM”) are used in computer systems. Static random-access memory (“SRAM”), as opposed to dynamic RAM, is a type of volatile memory that does not require refreshing in order to retain the data it holds. Typically, the cells of SRAM will remain stable and retain the data they hold until they are driven to a new state, or are powered off.

Like many types of computer memory, SRAM often consists of a large array of individual, repeating memory cells. In SRAM, each memory cell may be a circuit with at least two stable states. In a typical computer system, the two states usually include a high voltage output state, that can represent a digital “1,” and a low voltage output state, that can represent a digital “0”. Of course, the high voltage could represent “0,” and the low voltage could represent “1,” if desired.

External circuitry can be used to read and write (i.e. drive) the state of each memory cell. Once written, the memory cell will retain the state until a new state is written, or until the memory cell is powered off.

Occasionally, transient external factors can cause an SRAM to erroneously change its state. For example, the state can change in the presence of undesired events or stimulus such as radiation, a spike or dip on a voltage rail, or a spike or dip on a ground rail. These unintentional changes in state can cause faults or failures by corrupting data stored in the SRAM, which can lead to problems such as computer crashes, corrupted files, halted execution of a program, and the like. Faults or failures can be particularly problematic in systems that require stable, consistent, and error free operation, or in systems that operate in environments where fault-causing events are common. Such systems include computing systems on satellites or space stations where radiation is common, computing systems in factory or manufacturing environments, or on sea-bound ships, where power and ground spikes can be common, etc. Other environments where fault-causing events are frequent are planetary orbit, deep space, proximity to nuclear reactors, military applications, etc.

### SUMMARY OF THE INVENTION

According to an embodiment of the present invention, there is provided a memory apparatus that includes a pathway for conducting electrical energy, a plurality of even number of inverters, each inverter having an input and an output, the inverters being arranged along the pathway such that electrical energy from the output of an inverter is directed into the input of an adjacent inverter, and a plurality of nodes coupling the inverters in series to form a closed loop to permit stable storage of a memory state by allowing the inverters to dissipate an amount of transient energy from a level that otherwise would result in a failure to below that level in order to maintain a stable memory state.

Further according to the embodiment, one of the nodes is coupled to one of the inputs of the inverters for receiving a signal that reads a memory state stored in the loop or writes a memory state to be stored in the loop.

Further according to the embodiment, the loop permits a memory state to be read from the node or written to the node while one of the inverters is defective or damaged.

Further according to the embodiment, in the memory apparatus, each inverter is reinforced by at least two adjacent inverters including an inverter adjacent to the input and an inverter adjacent to the output.

Further according to the embodiment, the even number of the plurality of inverters is chosen according to an amount of transient energy known to cause a fault.

According to another embodiment of the present invention, there is provided a method of providing a fault-tolerant memory cell, the method includes the steps of conducting electrical energy along a pathway, arranging a plurality of even number of inverters along the pathway, each inverter having an input and an output, such that energy from the output of an inverter is directed into the input of an adjacent inverter, and coupling the inverters to a plurality of nodes in series to form a closed loop to permit stable storage of a memory state by allowing the inverters to dissipate an amount of transient energy from a level that otherwise would result in a failure to below that level in order to maintain a stable memory state.

According to another embodiment of the present invention, there is provided a memory device that includes a plurality of memory cells, each memory cell including a pathway for conducting electrical energy, a plurality of even number of inverters, each inverter having an input and an output, the inverters being arranged along the pathway such that electrical energy from the output of an inverter is directed into the input of an adjacent inverter, and a plurality of nodes coupling the inverters in series to form a closed loop to permit stable storage of a memory state by allowing the inverters to dissipate an amount of transient energy from a level that otherwise would result in a failure to below that level in order to maintain a stable memory state.

### DESCRIPTION OF THE DRAWINGS

FIG. 1 is a logical diagram of a memory cell having two inverters;

FIG. 2 is a schematic diagram of a two-inverter memory cell;

FIG. 3 depicts a memory cell having four inverters according to an embodiment;

FIG. 4 depicts a memory cell having six inverters according to another embodiment;

FIG. 5 depicts a two-inverter memory cell driven by an external circuit;

FIG. 6 depicts an embodiment of a four-inverter memory cell driven by an external circuit;

FIG. 7 depicts an embodiment of a four-inverter memory cell driven by an external circuit.

### DETAILED DESCRIPTION

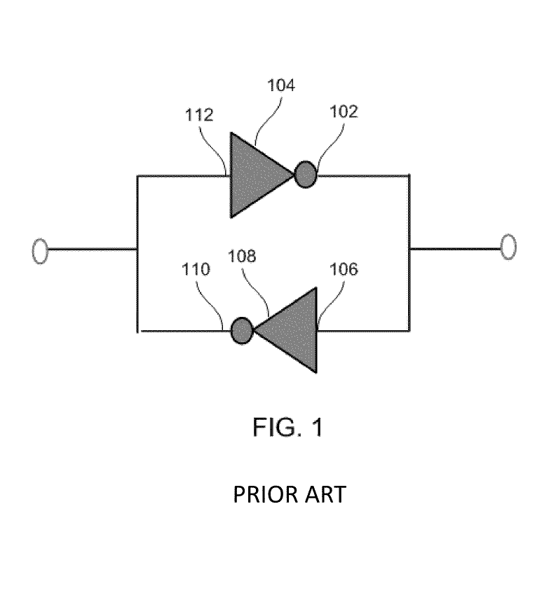

As shown in FIG. 1, two complementary inverters may be used to implement an SRAM cell and maintain a stable, high or low voltage state. As shown, the output 102 of inverter 104 can be coupled to the input 106 of inverter 108, and the output 110 of inverter 108 can be coupled to the input 112 of inverter 104. In such an arrangement, the two inverters will reinforce each other's state, and hold each other in a stable state. For example, assume that in a first stable state, the output 102 of inverter 104 is low, thus driving the input 106 of inverter 108 low. In this case, since the input 106 is low, inverter 108 will drive output 110 high, thus driving the input 112 of inverter 104 high. Since input 112 of inverter 104 is high, the output 102 of inverter 104 will remain low, thus reinforcing the “low” output 102 from inverter 108.

Now, assume that in a second stable state, the output 102 of inverter 104 is high. In this case, the output 102 will drive the input 106 of inverter 108 high. Since the input 106 is high, inverter 108 will drive output 110 low, thus driving the input 112 of inverter 104 low. Since input 112 of inverter 104 is low, the output 102 of inverter 104 will remain high, thus reinforcing the “high” output 102 from inverter 108.

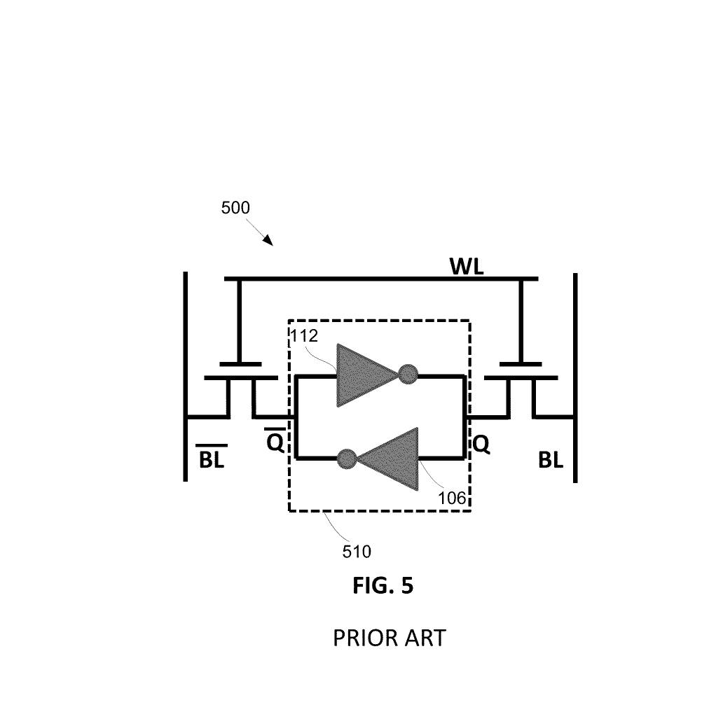

As shown in FIG. 5, in order to change the state of the SRAM cell, external circuitry 500 can drive the inverter inputs 112 and 106 to the desired level, and hold the inputs at those levels until the inverters throughout the SRAM cell stabilize in the new state.

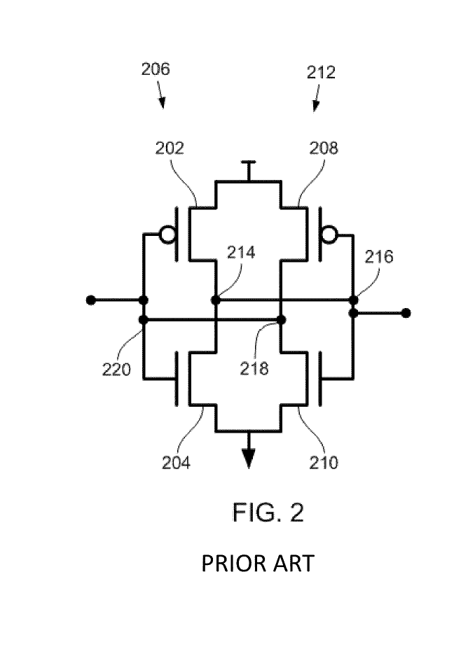

The most common implementation of the SRAM employs silicon complementary metal-oxide-semiconductor (CMOS) fabrication technology. Each inverter includes two metal-oxide-semiconductor (MOS) field-effect transistors (FETs). For example, as shown in FIG. 2, FETs 202 and 204 compose a first inverter 206, and FETs 208 and 210 compose a second inverter 212. As shown, the output 214 of inverter 206 is coupled to the input 216 of inverter 212, and the output 218 of inverter 212 is coupled to the input 220 of inverter 206 to form an SRAM cell. As shown in FIG. 5, the external read/write circuitry for an SRAM cell may require additional two or more FETs. Hence, each SRAM cell may include six FETs.

Of course, one may construct inverters and/or SRAM cells with other silicon technologies (NMOS or PMOS or bipolar, etc.) and with other, non-silicon semiconductors. Further, even non-semiconductor technologies (vacuum tubes, optical fibers, and quantum devices, for example) may serve as the underlying technology for inverters and/or SRAM cells.

As discussed, an SRAM cell can be formed by two inverters, as shown in FIGS. 1 and 2. However, such an SRAM call can be susceptible to faults. When a burst of ionizing radiation, a voltage or ground spike, or another fault-causing event is present, the fault-causing event will often affect, or be localized to, one of the FETs. These transient surges of energy may upset the operation of the inverters. For example, assume a burst of radiation hits the upper-right P-channel FET 208, and assume that drain node 218 of FET 208 is initially at Ground. The effect of the flood of electron-hole pairs generated by the radiation may be able to discharge through drain node 218 and attempt to pull the potential to +V. The lower-right N-channel FET 210 will oppose this action since the gate of this FET is initially “on” and, thus, this FET 210 provides a connection to Ground. But as the drain node 218 of the upper-right P-channel FET 208 is pulled to higher potential by the radiation spike, the gate of the lower-left N-channel FET 204 is pulled to higher potential as well. This action may turn “on” the lower-left N-channel FET 204, which may have the effect of pulling the potential of the drain node of the lower-left N-channel FET 204 to a lower potential (i.e. closer to Ground). Moving the potential at this node closer to Ground also shuts off the gate of the lower-right N-channel FET 210 which weakens the ability of the SRAM cell to oppose and reverse the radiation-induced transient energy that initially upset the potential at drain node 218 of the upper-right P-channel FET 208.

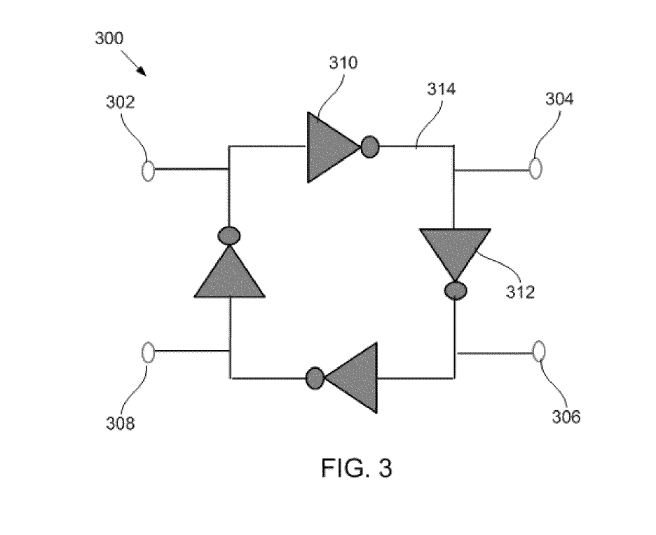

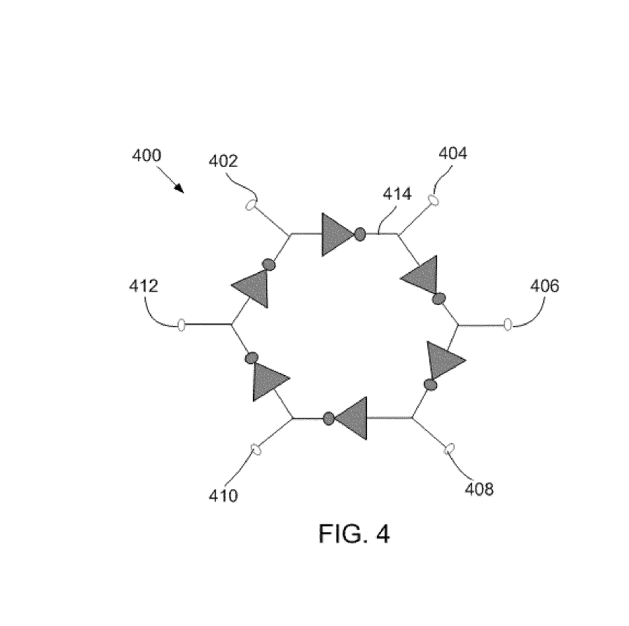

In order to reduce the chance for such faults to occur, according embodiments of the present invention, an SRAM cell can be provided with multiple pairs of inverters arranged in a closed loop in series, as shown in FIGS. 3 and 4.

Certain exemplary embodiments will now be described. Further embodiments are within the scope of the claims.

In one embodiment, the SRAM cell can incorporate two pairs of inverters, for a total of four inverters, as shown in FIG. 3. In another embodiment, the SRAM cell can incorporate three pairs of inverters, for a total of six inverters, as shown in FIG. 4. Other embodiments can include additional inverters connected in series. In general, the SRAM call can include any number of inverters, so long as the number is an even number (4, 6, 8, 10 inverters, etc.) to allow the closed loop of inverters to reinforce each other in a stable state.

Further, additional embodiments can include even numbers of inverters arranged in two or more loops. The loops are arranged such that each of the loops is coupled to each of the other loops so as to reinforce each of the inverters in any of the loops.

As shown in FIGS. 3 and 4, the inverters may be coupled together so that the output of any inverter is connected to the input of an adjacent inverter, to allow the inverters to form a closed chain or loop and act as a stable SRAM cell. FIG. 3 shows an SRAM cell 300 with four inverters, and FIG. 4 shows an SRAM cell 400 with six inverters. SRAM cells with more than six inverters are also within the scope of the invention.

The four-inverter loop of FIG. 3 and the six-inverter loop of FIG. 4 can have two possible states. Using SRAM cell 300 (in FIG. 3) as an example, in a first stable state, nodes 302 and 306 may be “high,” while nodes 304 and 308 may be “low.” In a second stable state, nodes 302 and 306 may be “low,” while nodes 304 and 308 may be “high.” Similarly, as shown in FIG. 4, in a first stable state, nodes 402, 406, and 410 of SRAM cell 400 may be “high,” while nodes 404, 408, and 412 may be “low.” In a second stable state of SRAM cell 400, nodes 402, 406, and 410 may be “low,” while nodes 404, 408, and 412 may be “high.” In general, as more inverters are added to the loop of inverters, the state of each node may alternate along the length of the loop so that the loop of inverters maintains a stable state.

In particular, each of the inverters in FIGS. 3 and 4 are enforced by two adjacent inverters, which are further enforced by their adjacent inverters.

When writing information to the SRAM cell, external circuitry can be used to drive a desired voltage input. The external circuitry may, in an embodiment, discharge the old state while charging the new state. In the four-inverter loop shown in FIG. 3, inverters are arranged around a conductive pathway 314 such that energy from the output of an inverter is directed to the input of an adjacent inverter. Further, a plurality of nodes 302, 304, 306, and 308 are coupled to the inverters in series to form a closed loop. The external circuitry may drive all four nodes 302, 304, 306, and 308 when writing a new state with two nodes being driven “High” and two nodes being driven “Low” in alternating sequence around the loop. When all four nodes are driven, the time required to set the new memory state should be relatively low, comparable to that of a two-inverter memory cell since each node is driven to the desired state by the external circuitry. Alternatively, the external circuit may drive fewer than all four nodes when writing a new state to the memory cell. In this case, the time required for writing the new state may be higher than that of a two-inverter memory cell because the desired state may have to propagate through multiple inverters.

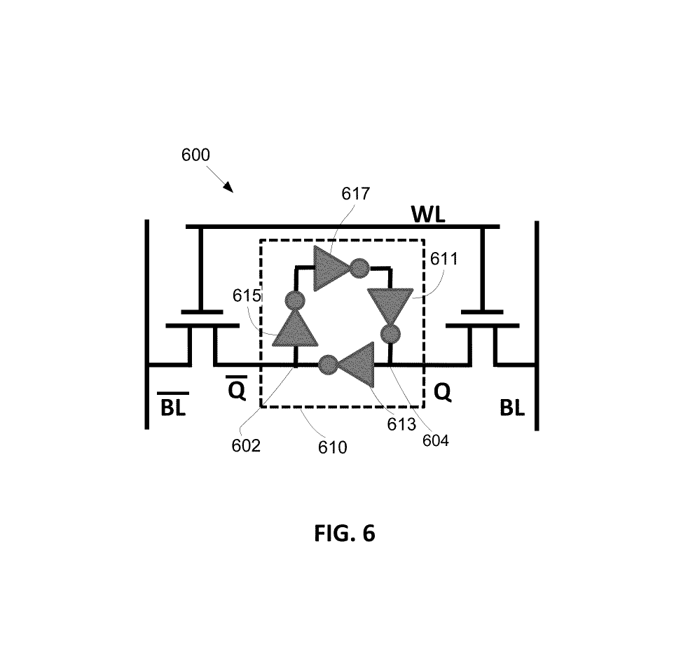

As an example of the external circuit for driving a four-inverter SRAM, FIG. 6 depicts an external circuit 600 for driving a four-inverter memory cell 610. As shown, two of the nodes, nodes 602 and 604, are driven by the external circuit 600.

For example, if an input voltage is driven onto a single node of SRAM cell 300 in FIG. 3, more time may be required for the SRAM cell 300 to change state. This is because the desired state must propagate through the entire loop of four inverters. The required time can be reduced, however, by driving multiple nodes along the length of the loop. For example, looking at SRAM cell 300 in FIG. 3, if a desired voltage is driven onto nodes 302 and 306, then the desired state only has to propagate through two inverters, which can take less time than propagating through all four inverters. In this case, the voltage driven onto node 302 only has to propagate through inverters 310 and 312 to reach node 306. It does not have to propagate beyond node 306 because node 306 is also being driven to the desired voltage by the external circuitry. If a desired voltage is driven onto all nodes 302, 304, 306, and 308, then the desired state only has to propagate through one inverter, and may take even less time for the SRAM cell to reach a stable state.

Similarly, as shown in FIG. 4, 6 inverters are arranged around a conductive pathway 414 such that energy from the output of an inverter is directed to the input of an adjacent inverter. Further, a plurality of nodes 402, 404, 406, 408, 410, and 412 are coupled to the inverters in series to form a closed loop. The external circuitry may drive all six nodes 402, 404, 406, 408, 410, and 412 when writing a new state with three nodes being driven “High” and three nodes being driven “Low” in alternating sequence around the loop. Alternatively, the external circuit may drive fewer than all six nodes when writing a new state to the memory cell.

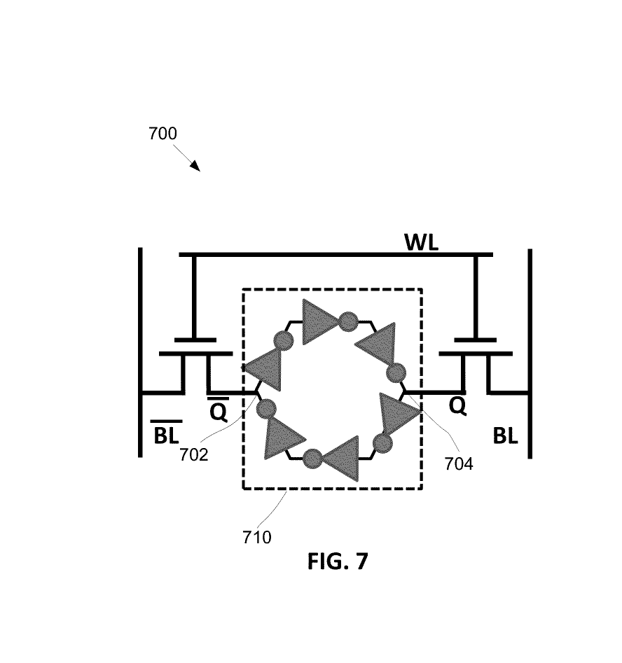

As an example of the external circuit for driving a six-inverter SRAM, FIG. 7 depicts an external circuit 700 for driving a six-inverter memory cell 710. As shown, two of the nodes, nodes 702 and 704, are driven by the external circuit 700.

Since an SRAM cell of the present invention can include any even number of inverters (four in case of the SRAM cell 300 in FIG. 3, six in case of the SRAM cell 400 in FIG. 4, eight, ten, etc.), the external circuitry that writes the state of the SRAM cell can drive any number of inverter inputs. In some embodiments, the external circuitry can drive all the inverter inputs in order to write the SRAM state. In other embodiments, the external circuitry can drive fewer than all of the inverter inputs and as few as one inverter input, in order to write the SRAM state.

Therefore, the four-inverter loop 610 of FIG. 6, the six-inverter loop 710 of FIG. 7, as well as larger loop of inverters, can function as an SRAM cell. Furthermore, the four-inverter loop 610 and larger loop of inverters, e.g. the six-inverter loop 710, when implemented as SRAM cells according to the present invention, provides greater immunity or tolerance to events that cause faults.

Using radiation as an example of a fault-inducing event, radiation collision and damage can be highly localized, and may typically affect individual FETs or inverters within a SRAM cell. For instance, when radiation collides with one of the inverters of a conventional two-inverter SRAM cell, this cell is much more likely to erroneously “flip” state (i.e., change state without the external circuitry driving a desired state). This is because the error condition only has to propagate through a short chain of inverters in order to change the state of the SRAM cell. In other words, for a radiation event that discharges a known amount of transient energy in to the memory cell, a two-inverter cell may not dissipate enough of the transient energy before the error condition propagates to the other inverter that would have reinforced the memory state to recover to the memory state prior to radiation.

On the other hand, by providing a four-inverter SRAM cell (or an SRAM cell with more than four inverters) according the present invention, the error condition would need to propagate through a longer chain of inverters in loop 610 (see FIG. 6) in order to flip the state of the SRAM cell 600. Assuming, for example, inverter 611 is affected by the error condition. Then the error condition needs to propagate through inverters 613, 615, and 617 in order to flip the state of the SRAM cell 610. This is because the additional inverters 613, 615, and 617 act to stabilize the SRAM cell 600 in its current state. In particular, each of the inverters is reinforced by at least two adjacent inverters. With respect to inverter 611, inverters 613 and 617 are adjacent inverters that flank inverter 611 by being coupled to the input and output of inverter 611. Inverter 615 is an adjacent inverter with respect to inverter 611 by being coupled adjacent to a flanking inverter 613. Here, the remaining three inverters 613, 615, and 617, where the radiation did not collide, can act to restore the radiation-struck inverter 611 to its original state, thereby preserving the memory of the entire SRAM cell 610 in the instant following the burst of radiation energy.

To provide additional clarity, consider the conventional two-inverter chain SRAM cell in FIGS. 1, 2 and 5. When a radiation induced failure occurs, the radiation can disrupt an isolated element of the SRAM cell 510 (either a single transistor or an inverter). The other element of the transistor or the other inverter of the SRAM cell 510 may succeed in quashing the disruption and setting the SRAM cell back to its initial state. However, when they cannot quash the disruption, the radiation-induced fault would be great enough to reset the potentials throughout both inverters, and flip the state of the entire SRAM cell 510. Once flipped, the SRAM cell 510 can stabilize in the new state, and retain the erroneous state until a new state is written to the SRAM cell.

The four-inverter SRAM cell 610 (see FIG. 6) of the present invention, by design, can provide greater stability, and can be more tolerant to failures, because radiation-induced charge—generally isolated to just one node—is much less likely to disrupt the larger number of inverters in our embodiment by propagating through the longer chain. Likewise, as provided by the four or more inverters of the present invention, a six-inverter SRAM cell 710 (see FIG. 7) may provide more stability and fault tolerance than either the two-inverter or four-inverter SRAM cells. Although not expected, adding more inverters may further increase the stability and resistance of the SRAM cell to ionizing radiation. This is because each additional inverter arranged in the closed loop can successively dissipate the transient energy as the error condition propagates along the loop, thereby making subsequent error propagation less likely.

Therefore, a four-inverter memory cell 610 of the present invention can dissipate an amount of transient energy from a level that otherwise would result in a failure in a conventional two-inverter memory cell 510 (see FIG. 5) to below that level in order to maintain a stable memory state. Similarly, a six-inverter memory cell 710 of the present invention can dissipate an amount of transient energy from a level that otherwise would result in a failure in a conventional two-inverter memory cell, or in a four-inverter memory cell 610 to below that level in order to maintain a stable memory state.

The four-inverter SRAM cell 600 (see FIG. 6) according to the present invention can be more immune to permanent damage such as dislocations of the silicon lattice or other materials caused by radiation (such as neutrons and heavier particles). The localized nature of the damage means that one individual FET within an inverter may be permanently damaged such that the FET does not turn completely “on” or completely “off” as desired. The two stable states of the four-inverter loop 610 of the present invention can be more tolerant of a resulting defect in one inverter than are the stable states of the conventional two-inverter chain. In addition, a six-inverter SRAM cell 710 of the present invention can provide more tolerance against permanent defects than both the two-inverter and four-inverter SRAM cells 610. As noted previously, it is observed in connection with the present invention that adding more inverters further increases the tolerance of the SRAM cell to isolated defects.

Conventional techniques for improving the fault-tolerance of conventional (two-inverter chain) SRAM cells, which do not increase the number of inverters, may be used in combination with the embodiments of the present invention to provide additional fault tolerance to error conditions. These techniques include increasing the cell capacitance and minimizing the semiconductor layer in which the cell is fabricated. All such techniques can also be applied in combination with the embodiments of the present invention to provide a level of radiation-hardness superior to either technique alone.

In addition to radiation-hardness, the design of memory cells according to the present invention also provide a greater fault tolerance relative to errors in fabrication and design and in imperfection of materials, as well as fault tolerance of other external stimuli such as ground or voltage rail spikes and dips. Further benefits may become apparent over time.

While the invention has been described in connection with specific embodiments, it will be understood that it is capable of further modification. Furthermore, this application is intended to cover any variations, uses, or adaptations of the invention, including such departures from the present disclosure as come within known or customary practice in the art to which the invention pertains.

What is claimed is:

1. A memory apparatus comprising:
a pathway for conducting electrical energy;
a plurality of even number of inverters, each inverter having an input and an output, the inverters being arranged along the pathway such that electrical energy from the output of an inverter is directed into the input of an adjacent inverter;
a plurality of nodes coupling the inverters in series to form a closed loop to permit stable storage of a memory state by allowing the inverters to dissipate an amount of transient energy from a level that otherwise would result in a failure to below that level in order to maintain a stable memory state.

2. The apparatus of claim 1, wherein
One of the nodes is coupled to one of the inputs of the inverters for receiving a signal that reads a memory state stored in the loop or writes a memory state to be stored in the loop.

3. The apparatus of claim 2, wherein the node is configured to receive a voltage signal.

4. The apparatus of claim 2, wherein
the loop permits a memory state to be read from the node or written to the node while one of the inverters is defective or damaged.

5. The apparatus of claim 2, further comprising:
an external circuitry coupled to the node for providing a signal to read a memory state stored in the loop, or to write a memory state to be stored in the loop.

6. The apparatus of claim 1, wherein each inverter is reinforced by at least two adjacent inverters including an inverter adjacent to the input and an inverter adjacent to the output.

7. The apparatus of claim 1, wherein the even number of the plurality of inverters is chosen according to an amount of transient energy known to cause a fault.

8. The apparatus of claim 1, wherein the inverters are constructed with any of silicon or non-silicon semiconductor technologies including CMOS, NMOS, PMOS, or bipolar semiconductors, or vacuum tubes, optical fibers, and quantum devices.

9. The apparatus of claim 1, wherein the inverters provide additional fault-tolerance to the error condition by, at least one of, being constructed with high cell capacitance, and being fabricated with minimal semiconductor layers.

10. A method of providing a fault-tolerant memory cell, comprising:
conducting electrical energy along a pathway;
arranging a plurality of even number of inverters along the pathway, each inverter having an input and an output, such that energy from the output of an inverter is directed into the input of an adjacent inverter;
coupling the inverters to a plurality of nodes in series to form a closed loop to permit stable storage of a memory state by allowing the inverters to dissipate an amount of transient energy from a level that otherwise would result in a failure to below that level in order to maintain a stable memory state.

11. The method of claim 10, further comprising:
coupling one of the nodes to one of the inputs of the inverters for receiving a signal that reads a memory state stored in the loop or writes a memory state to be stored in the loop.

12. The method of claim 11, wherein
the loop permits a memory state to be read from the node or written to the node while one of the inverters is defective.

13. The method of claim 11, further comprising:
coupling an external circuitry to the node for providing a signal to read a memory state stored in the loop, or to write a memory state to be stored in the loop.

14. The method of claim 10, wherein each inverter is coupled to two adjacent inverters including an inverter adjacent to the input and an inverter adjacent to the output, so as to be energetically reinforced by the two adjacent inverters.

15. The method of claim 10, wherein a number of the plurality of inverters is chosen according to an amount of transient energy known to cause a fault.

16. A memory device comprising:
a plurality of memory cells, each memory cell including:
a pathway for conducting electrical energy;
a plurality of even number of inverters, each inverter having an input and an output, the inverters being arranged along the pathway such that electrical energy from the output of an inverter is directed into the input of an adjacent inverter;
a plurality of nodes coupling the inverters in series to form a closed loop to permit stable storage of a memory state by allowing the inverters to dissipate an amount of transient energy from a level that otherwise would result in a failure to below that level in order to maintain a stable memory state.

17. The memory device of claim 16, wherein, for each memory cell,
one of the nodes is coupled to one of the inputs of the inverters for receiving a signal that reads a memory state stored in the loop or writes a memory state to be stored in the loop.

18. The memory device of claim 17, wherein, for each memory cell, the node is configured to receive a voltage signal.

19. The memory device of claim 17, wherein, for each memory cell,
the loop permits a memory state to be read from the node or written to the node while one of the inverters is defective or damaged.

20. The memory device of claim 16, wherein, for each memory cell, each inverter is reinforced by at least two adjacent inverters including an inverter adjacent to the input and an inverter adjacent to the output.
